(19) United States
(12) Patent Application Publication
(10) Pub. No.: US 2021/0112690 A1
(43) Pub. Date: Apr. 15, 2021

(54) THERMOELECTRIC COOLERS FOR ELECTRONICS COOLING

(71) Applicant: BAE Systems Controls Inc., Endicott, NY (US)

(72) Inventors: Nicholas Lemberg, Vestal, NY (US); Arnold Ahnood, Endicott, NY (US); Kolin Arnold, Vestal, NY (US); Filippo Muggeo, Endwell, NY (US)

(73) Assignee: BAE Systems Controls Inc., Endicott, NY (US)

(21) Appl. No.: 16/596,990

(22) Filed: Oct. 9, 2019

(51) Int. Cl. H05K 7/20; G06F 1/20

(52) U.S. Cl. CPC H05K 7/20945; H05K 7/20509; G06F 1/206

(57) ABSTRACT

An apparatus for cooling electronic components includes a chassis having a hot side compartment having one or more first electrical components and a cold side compartment having one or more second electrical components. A coolant channel is connected to the cold side compartment. At least one thermoelectric cooler (TEC) is positioned within the cold side compartment. The TEC has a cold plate and a hot plate, the hot plate being connected to the coolant channel and the cold plate being connected to the one or more second electrical components. A method for cooling electronic components using at least one TEC includes identifying an amount of heat to be removed from the one or more second electronic components and determining the TEC with the peak performance based on a best Delta T. The method includes monitoring the Delta T and adjusting the input voltage to maintain the optimum Delta T.

### BACKGROUND

The present disclosure relates to systems for cooling electronics and more particularly to systems for providing localized cooling for electronics.

Thermoelectric coolers have been used to provide cooling for electronics. Localized cooling is used in applications where even the coolant is hotter than some electronics can reasonably tolerate. In one example, this scenario may occur when using a coolant for electronics that is shared with an internal combustion engine. In such a scenario, some integrated circuits struggle to both operate normally and deliver long term reliability. In such a scenario below ambient cooling is highly desired for both performance and reliability reasons for at least some temperature sensitive electronics.

### SUMMARY

An apparatus for cooling electronic components, in one embodiment, includes a chassis having a first side compartment having one or more first electrical components and a second side compartment having one or more temperature sensitive electrical components. A coolant channel runs between the two compartments. At least one thermoelectric cooler (TEC) is positioned within the second side compartment. The TEC has a cold plate and a hot plate, the hot plate being connected to a base of the second compartment and the cold plate being connected to the one or more temperature sensitive electrical components.

Various other embodiments include where the coolant channel may be part of a water-ethylene glycol cooler assembly. The coolant channel may be connected to a cooling loop of an internal combustion engine. The electrical components may include high temperature capacitors. The temperature sensitive electrical components may be contained on a circuit card assembly. Larger components may also be cooled as well. The apparatus may further include a thermal insulator positioned between the coolant channel and the one or more second electrical components. The thermal insulator may be configured to prevent heat transfer between the coolant channel and the one or more second electrical components. The TEC may be configured to bring the temperature of the one or more first electronic components below the temperature of the coolant channel.

A method for cooling electronic components using at least one TEC, in one embodiment, includes providing an apparatus including a chassis having a first side compartment having one or more first electrical components and a second side compartment having one or more temperature sensitive electrical components, as well as a coolant channel connected therebetween. The method includes identifying an amount of heat to be removed from the one or more temperature sensitive electronic components, in one example, determining TEC peak performance according to the formula PKP=Delta T*N, where Delta T is the temperature difference between the hot plate and cold plate of the TEC, and N=HR/IP, where HR is the identified heat to be removed and IP is the input power supplied to the TEC. The method also provides for positioning at least one TEC meeting the peak performance for the identified heat removal from the temperature sensitive electrical components.

The method may further include operating the at least one TEC to maintain the Delta T according to a predetermined relationship between input voltage and a coefficient of performance of the at least one TEC. The method may further include monitoring the Delta T of the at least one TEC during operation and adjusting the input voltage to maintain the Delta T according to the predetermined relationship between input voltage and the coefficient of performance of the at least one TEC.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1A is perspective view of one embodiment of the hot side/cold side chassis according to the present disclosure with the hot side on top.

FIG. 1B is side view of one embodiment of the hot side/cold side chassis according to the present disclosure with the hot side on top.

FIG. 1C is perspective view of one embodiment of the hot side/cold side chassis according to the present disclosure with the cold side on top.

FIG. 2 is a block exploded view schematic diagram of one embodiment of the apparatus for cooling electronic components according to the present disclosure.

FIG. 2A is a block exploded view schematic diagram of one embodiment of the apparatus for cooling electronic components according to the present disclosure including a heat spreader layer.

FIG. 2B is a block exploded view schematic diagram of one embodiment of the apparatus for cooling electronic components according to the present disclosure including a surface copper layer.

FIG. 2C is a block exploded view schematic diagram of one embodiment of the apparatus for cooling electronic components according to the present disclosure including a gap pad.

FIG. 3 is a graph showing the linear relationship between the heat removed N and the temperature difference Delta T.

FIG. 4 is a graph of the relationships between the input current and Delta T.

FIG. 5 shows the relationships between the coefficient of performance and the input voltage.

FIG. 6 is a flow chart of one embodiment of a method for controlling a TEC for peak performance.

FIG. 7 illustrates a schematic of an example computer or processing system that may implement the method for controlling a TEC for peak performance in one embodiment of the present disclosure.

### DETAILED DESCRIPTION

In one embodiment, a first side compartment and second side compartment chassis is provided together with the strategic placement of one or more thermoelectric coolers (TECs). The combination of the first side-second side chassis and the strategically placed TECs provides localized cooling for certain more temperature sensitive electronics. The localized cooling can bring the electronic components being cooled below the local ambient temperature of the compartments.

In one embodiment, the TECs are placed between a base of the second side compartment and the electronic components. In one embodiment, specifically designed circuit card assemblies containing the electronic components are used. In one embodiment, the circuit card assemblies may include a layer designed to drive heat to towards the TECs point of contact. In another embodiment, the circuit card assemblies may include a layer designed to spread the TECs zone of cooling influence.

The solution provided by the present disclosure is superior as it allows localized cooling for those temperature sensitive components while allowing the rest of the system to remain at higher levels. For example, if that coolant temperature was 105° C., which is common in internal combustion engine coolant loops, then all the components being cooled by that coolant and within the first and second side compartments would be operating at temperatures about or in excess of 105° C. Considering that some components have some form of dependency on temperature (timing skew, resistance, capacitance, etc) and that for a typical datasheet they are benchmarked at temperatures below 105° C., then the circuits that are designed using these components can struggle to stay within the intended design window without special care being taken to include this dependency on temperature. In one embodiment, temperature sensitive components are those that require or perform better at temperatures lower than the ambient temperatures of the side compartments. In this example, if the operating ambient second side compartment temperature was 105° C., the temperature sensitive components would be those that operate optimally below that level.

Furthermore components that are temperature sensitive and run hot will have a shorter operational life, which can impact performance as the components degrade over time. Additionally premature component failure negatively impacts the product reliability. Therefore, using the present system for temperature sensitive components and providing below ambient temperatures extend the life of those components. Furthermore, by only cooling the required components, the overall system can be designed to minimize weight and expended energy in cooling components that do not require cooling thereby increasing efficiency.

In one example of an internal combustion engine, it desirable to use a 105° C. water-ethylene glycol (WEG) cooler assembly in order to use the engine loop to cool all vehicle components. A WEG is an efficient and highly reliable method of maintaining proper operating temperatures for power electronic components requiring liquid cooling. Under normal operating conditions, the WEG cooler assembly continually transports heat from the connected component via the water-ethylene glycol mixture to the heat exchanger. The heated fluid is then cooled in the heat exchanger/fan assembly and transported back to the connected component. The WEG cooler designed for internal combustion engine use maintains the coolant temperature below a maximum value of 105° C. for proper cooling of the connected components. Components such as Silicon Carbide (SiC) power modules and special higher temperature capacitors and the like, with a rating of 150° C. or higher, can be used with this hotter requirement. However, other circuit components cannot withstand this higher temperature environment or suffer from performance of longevity issues.

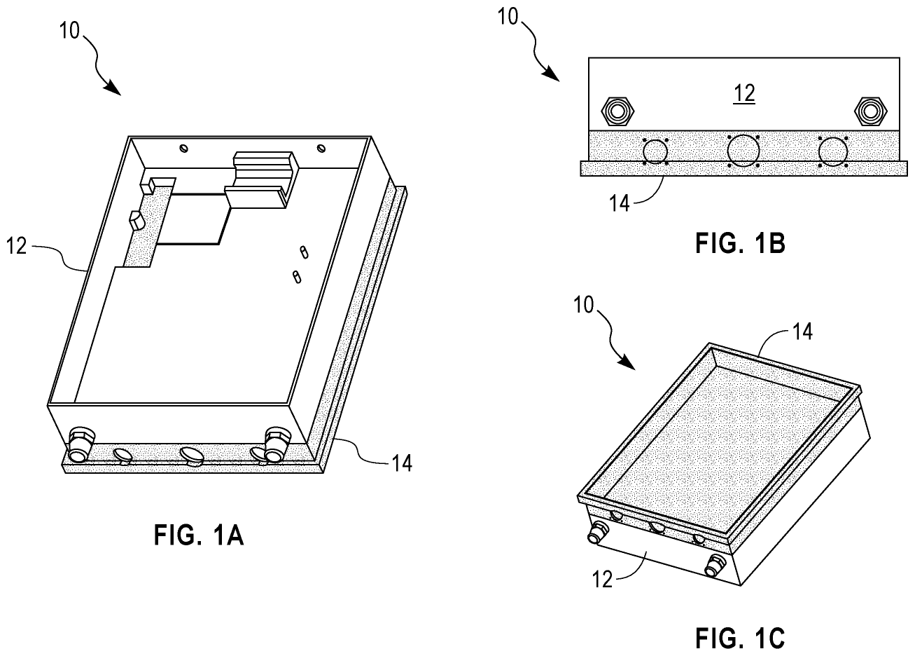

In one embodiment, as shown in FIGS. 1A, 1B and 1C, a dual chamber chassis 10 includes a first or hot side compartment 12 and a second or cold side compartment 14. The reference to cold side compartment 14 refers to the inclusion of thermoelectric coolers (TECs) in that compartment. In one example, the TECs are located in both the first and second compartments 12, 14. The compartments can further include connectors for liquid cooling as well as cabling holes for routing electric cables. The first and second side compartments 12, 14 are coupled together such that share a common central section with a cooling channel disposed therebetween that is coupled to a cooling fluid.

In one example, the electronic components that can tolerate and operate at a higher temperature can be located on the first side compartment 12 of the chassis 10. The first side compartment 12 is still subject to cooling but with a higher temperature coolant flow and establishes a first cooling area where electronics components reside. The first side compartment 12 is heat sunk to the coolant channel of the WEG and electronic components operate within the first side compartment 12. In one example the second side compartment 14 is heat sunk to the coolant channel of the WEG and electronic components operate within the second side compartment 14. Other temperature sensitive electronic components not directly compatible with the temperature of the first side compartment 12 can be placed in the second or cold side compartment 14 of the chassis 10 residing on one or more TECs. The second side compartment 14 in one example operates at a lower temperature (cooler) than the first side compartment 12. In another example the temperature of the first and second side compartments 12, 14 are approximately similar.

In one embodiment, some of the electronic components on the second side compartment 14 of chassis 10 operate in this second compartment that may or may not be cooler than the first compartment. In one example, one or more TECs are used in the second compartment and have a TEC hot side and a TEC cold side. The TEC hot side is connected to the base of the cold side compartment 14 and certain electronic components are connected to the cold side of the TECs.

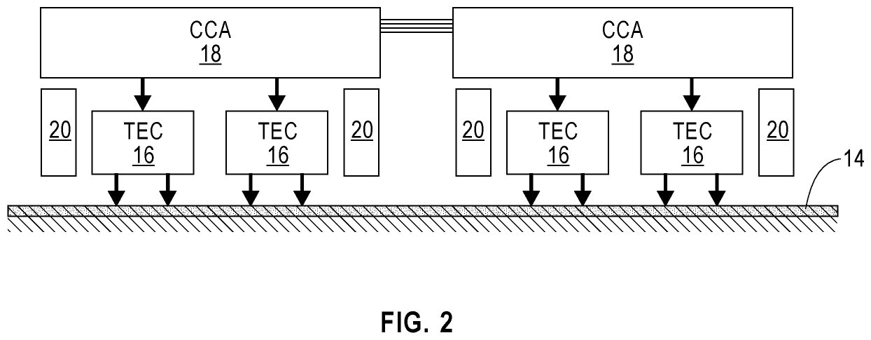

In one embodiment, the TECs can be used to establish localized cooling on the second side compartment 14 of the chassis 10. The TECs cool certain electronic components below the temperature of the second side compartment 14. In one embodiment, as shown in FIG. 2, TECs 16 are placed between the base of the second side compartment 14 and the certain electronic components 18. The TEC hot side 16 is coupled directly or indirectly to the second side compartment 14 of the chassis 10 and the electronic components 18 are coupled to the TEC cold side 16. The electronic components 18 may be located on a circuit card assembly or can be any other component or components. The TEC is designed to bring the temperature of the electronic components 18 below the temperature of second side compartment 14. FIG. 2 is an exploded view as the actual components will be attached. The arrows represent the direction of heat flow. Thermal insulators 20 may be used as standoffs to prevent heat transfer from the cold plate 14 to the electronic components 18.

As this is a partial view, in one example there are other electronic components within the second or cold side compartment 14 in addition to the components subject to localized cooling from the TECs. Any power required for the TEC can be accomplished by jumper wires from the electronic components 18 or a direct contact interface between connectors on the TEC and connectors on the electronic components. In a further example the TEC is coupled to a battery power source or from wiring external to the chassis. As one example, the TEC may have two wires for DC power that can be electrically connected to the circuit card assembly to provide power.

In yet a further embodiment, TECs are also arranged on the first side compartment 12, such that temperature sensitive electronic components are deployed on both the first and second side compartments on the TECs as noted herein. There may be other electronic components on the first and/or second side compartments in addition to the temperature sensitive components. The electrical components that are not temperature sensitive can be coupled to a substrate that is secured to the base of the first and/or second side compartment. The electrical components can also be coupled to the base directly or indirectly in one or both compartments. Electrical connections can be wires routed to the components, circuit traces on the base, or traces on circuit boards.

In one embodiment, the circuit card assemblies may include a layer designed to drive heat to towards the TECs point of contact. In another embodiment, the circuit card assemblies may include a layer designed to spread the TECs zone of cooling influence. As shown in FIG. 2A, in one embodiment, a metallic heat spreader layer 17 may be attached between the circuit card assembly 18 and the TEC 16. The layer 17 may be used for both single and dual sided boards. The heat spreader layer 17 connects hot parts/regions of the circuit card assembly 18 to TEC 16. A thermal interface material may be used to mount layer 17 to TEC 16. In another embodiment, the circuit card assemblies 18 may include a layer designed to spread the TECs zone of cooling influence. As shown in FIG. 2B, in one embodiment, a thick copper layer 19 is mounted on the surface of the circuit card assembly 18 to uniformly drive heat into TEC 16. The layer 19 may be used for single sided circuit boards. A thermal interface material may be used to mount layer 19 to TEC 16. As shown in FIG. 2C, the circuit card assembly 18 may be mounted to TEC 16 via a gap pad 21. Gap pad 21 can absorb differences in component height presenting a uniform flat surface for TEC mounting. The layer 21 may be used for single sided circuit boards. In one embodiment, copper thermal paths/traces internal to circuit board of the circuit card assembly 18 causes heat to travel through the circuit card assembly 18 to gap pad 21.

The thermoelectric cooler 16 in one example is a solid state device that utilizes the Peltier effect to create a heat flux between the junction of two different types of materials. More specifically, the thermoelectric cooler 16 includes a heat sink, a thermoelectric module, and/or the like that acts as a solid-state active heat pump to transfer heat from one side of the thermoelectric cooler 16 to the other with an input of electrical energy. The thermoelectric cooler 16 may include two unique semiconductor materials (an n-type and a p-type) that are placed thermally in parallel to each other and electrically in series, and then joined with a thermally conducting plate on each side. When a DC electric current is applied to the thermoelectric cooler 16, the thermoelectric cooler 16 brings heat from one side thereof to the other such that one side gets cooler while the other side gets hotter. The hot side is attached to a heat sink (such as the base of the second side compartment) so that it remains at ambient temperature, while the cool side exhibits temperatures that are below ambient temperature. A single-stage TEC in one example will typically produce a maximal temperature difference of 70° C. between its hot and cold sides. The more heat moved using a TEC, the less efficient it becomes, because the TEC needs to dissipate both the heat being moved and the heat it generates itself from its own power consumption. The amount of heat that can be absorbed is proportional to the current and time. The amount of heat absorbed by the cold side Q, is equal to PIt, where P is the Peltier coefficient, I is the current, and t is the time. The Peltier coefficient depends on temperature and the materials the TEC is made of.

In one embodiment, a method for selecting a TEC for peak performance is disclosed. Peak performance is defined as PKP=Delta T*N. Delta T is the temperature difference between the hot side and cold side of the TEC which is a predefined by the TEC manufacturer based on the voltage supplied to the device. N=HR/IP, where HR is the heat desired to be removed by the cold side of the TEC and IP is the input power supplied to the TEC device. The preferred performance is when N>1. The TEC is selected by identifying the required heat removal from the electronic components and then selecting the TEC device with the peak performance for the heat removal. The method yields the best Delta T, in other words the most efficient performance per Delta T.

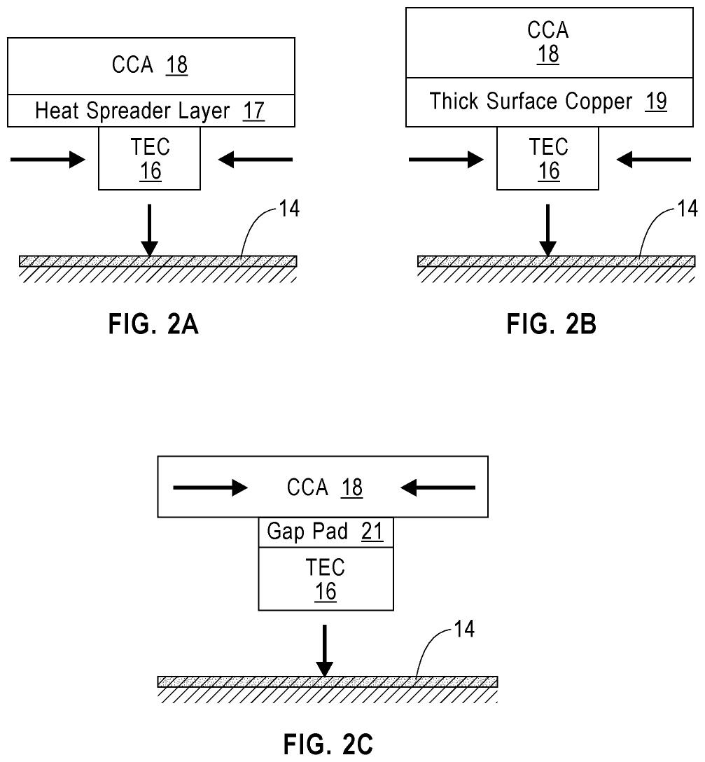

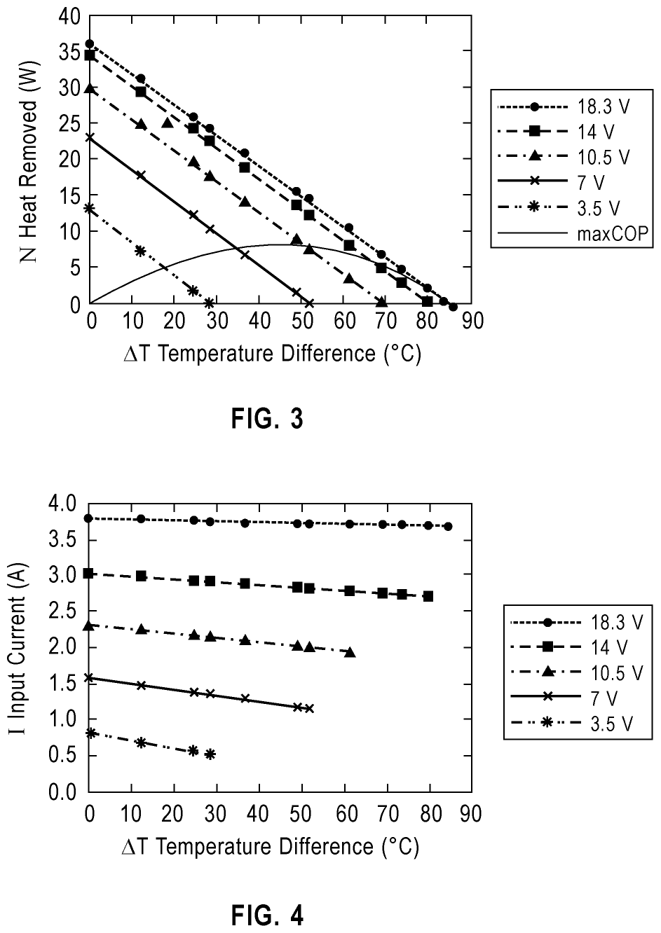

The graph in FIG. 3 shows the linear relationship between the heat removed N and the temperature difference Delta T for the five voltages specified by the manufacturer of the TEC device. The maxCOP line is the maximum coefficient of performance (COP). FIG. 4 is a graph of the relationships between the input current and Delta T for the five voltages specified by the manufacturer of the TEC device. The graphs available vary by manufacturer of the TEC. Therefore, the overall sequence for using the graphs for selecting the best TEC can vary. In one embodiment, first the heat to be removed (W) for the design is identified. This can be done by calculation but could also be obtained via other means. The second step is to determine, using the graph of FIG. 4, the input power required to establish a delta T. The next step then is to setup the calculation for performance using the graph of FIG. 3 by comparing the heat removed with temperature difference (delta T). This creates a vector with all the different delta Ts for the same input power and, using the information in the second step, each delta T has a power associated with it. From here the numbers are calculated and the answer for peak performance is the largest number. In one embodiment, the first and second steps could be swapped, determining the input power could be done later. In one embodiment, the vector can be setup first and then calculate input power just for the temperatures on the vector by including the voltage information supplied in the graph of FIG. 3.

The methods disclosed herein for selecting a TEC are an improvement over prior known methods. One known method uses heat removed/input power. However, this method does not then include delta T to determine a single optimum number. The single point found by including delta T allows comparison between different TECs.

In one embodiment, a method for providing a TEC to maximize cooling performance per watt is disclosed. TECs can be highly efficient if run at peak performance. In one embodiment, the method maximizes the relationship between delta T of the TEC and the power required for the TEC.

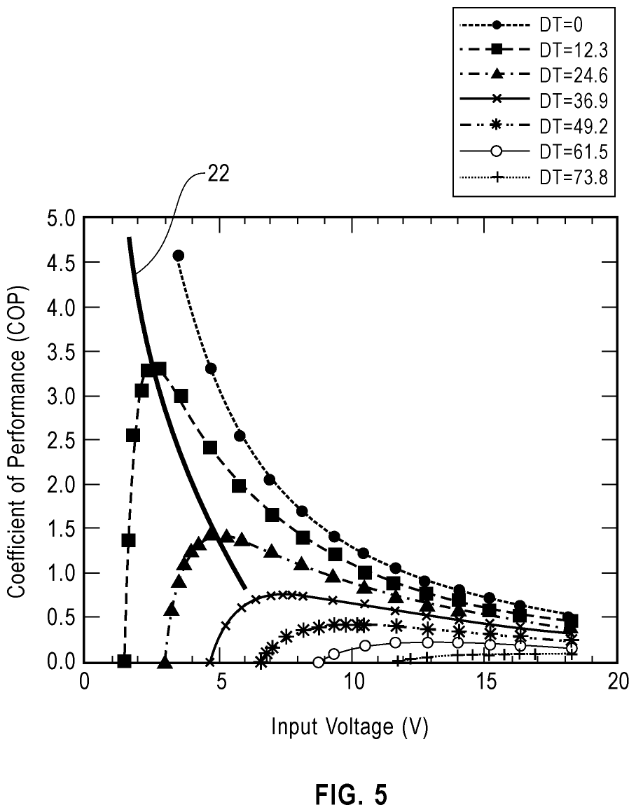

To achieve peak performance during operation, the TEC is operated at the best delta T identified during the design process. The graph of FIG. 5 shows the relationships between the coefficient of performance and the input voltage for the identified Delta Ts based on the graphs in FIGS. 3 and 4. Operating the TEC along the line 22 shown in FIG. 5 preserves optimum performance for the values of Delta T not flagged as best during the design process. For example, if the circuit has two TECs, it may desirable to minimize component variation so the same device is used for both. Therefore, in one case the device is completely optimized while the second installation is slightly off that same operating point due to differences in heat load etc. Alternatively, if the circuit has dynamic heat loading, keeping the device on the line is a way to preserve performance under the varying conditions. Operating to the right of line 22 indicates the device is undersized. Operating to the left of line 22 indicates the device is oversized. In practice to achieve peak performance the TEC should be operated with the minimum voltage required to achieve a target Delta T. For applications tolerant of different values of Delta T, the optimum performance is always found at the smallest acceptable value of Delta T.

Operational control revolves around understanding the target/acceptable Delta T. In one embodiment, a target temperature is identified and then a target Delta T is determined by comparing the target temperature to actual temperature during operation. If the target temperature as not being met, then the TEC device would need increased cooling which can be achieved by increasing Delta T. A greater Delta T can be achieved by increasing the applied voltage. Correspondingly if the TEC device is below the target temperature, then the Delta T should be reduced by decreasing the applied voltage.

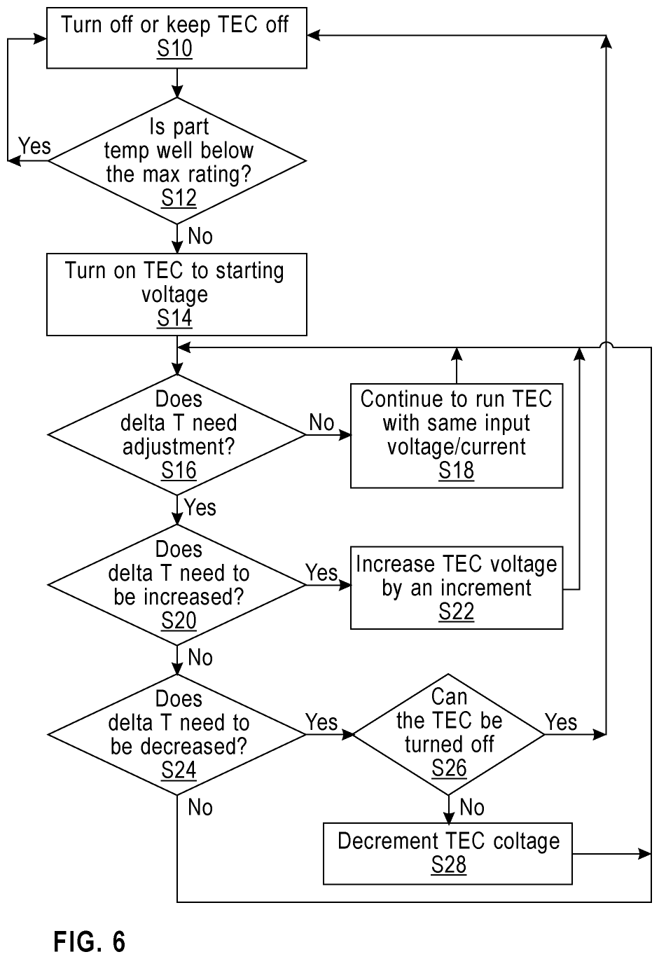

FIG. 6 is a flow chart of one embodiment of a method for controlling a TEC for peak performance. At the start of the method at step S10 the TEC is in the off condition or if on, is turned off. At step S12 the system determines whether the temperature of the electrical component to be cooled is well below the maximum rating for the component. If the temperature of the electrical component to be cooled is below the maximum rating for the component by a predefined threshold, YES at step S12, the method returns to step S10 to keep to the TEC off. If the temperature of the electrical component to be cooled is at or above the predefined threshold below the maximum rating for the component, NO at step S12, the TEC is turned on at step S14. The predefined threshold below the maximum rating for the component can be set by the user and will usually be based on the particular operating environment of the electrical component.

At step S16, the system measures the temperature and then determines whether Delta T needs to be adjusted in order to maintain the coefficient of performance on the peak performance line, such as that shown in FIG. 5. If Delta T does not need to be adjusted, NO at step S16, the TEC is operated at the present input voltage and current at step S18. If Delta T needs to be adjusted, YES at step S16, a determination is made whether Delta needs to be increased at step S20. If Delta T needs to be increased, YES at step S20, the TEC voltage is incremented by a predefined amount at step S22 and the process returns to step S16. If Delta T does not need to be increased, NO at step S20, a determination is made whether Delta T needs to be decreased at step S24. If Delta T needs to be decreased, YES at step S24, a determination is made whether the TEC can be turned off at step S26. For example, the TEC can be turned off if the system is turned off or if the coolant temperature is low enough that the added effect of TEC cooling is not required. If the TEC can be turned off, YES at step S26 the TEC is turned at step S10. If the TEC cannot be turned off, NO at step S26 the TEC is decremented a predefined amount at step S28. If Delta T does not need to be decreased, NO at step S24, the process returns to step S16.

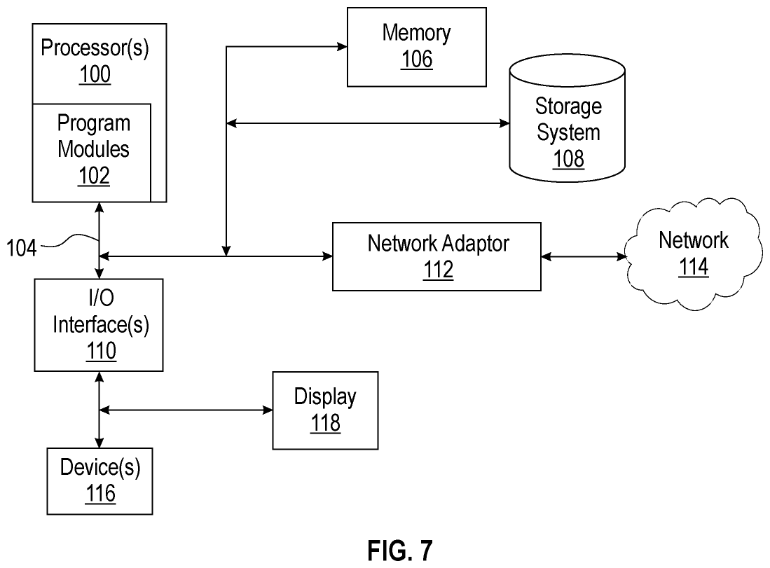

FIG. 7 illustrates a schematic of an example computer or processing system that may implement the method for controlling a TEC for peak performance in one embodiment of the present disclosure. The computer system would be used in conjunction with sensors to measure one or more of the input voltage, current and power, the current generated by the TEC, and the temperature of the hot plate and cold plate of the TEC and the temperature of the electrical components. The computer system is only one example of a suitable processing system that may be used to implement the method steps described and is not intended to suggest any limitation as to the scope of use or functionality of embodiments of the methodology described herein. The processing system shown may be operational with numerous other general purpose or special purpose computing system environments or configurations. Examples of well-known computing systems, environments, and/or configurations that may be suitable for use with the processing system shown in FIG. 7 may include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

The components of computer system may include, but are not limited to, one or more processors or processing units 100, a system memory 106, and a bus 104 that couples various system components including system memory 106 to processor 100. The processor 100 may include a program module 102 that performs the methods described herein. The module 102 may be programmed into the integrated circuits of the processor 100, or loaded from memory 106, storage device 108, or network 114 or combinations thereof.

Bus 104 may represent one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

The computer system may include a variety of computer system readable media. Such media may be any available media that is accessible by computer system, and it may include both volatile and non-volatile media, removable and non-removable media.

System memory 106 can include computer system readable media in the form of volatile memory, such as random access memory (RAM) and/or cache memory or others. Computer system may further include other removable/non-removable, volatile/non-volatile computer system storage media. By way of example only, storage system 108 can be provided for reading from and writing to a non-removable, non-volatile magnetic media (e.g., a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 104 by one or more data media interfaces.

The computer system may also communicate with one or more external devices 116 such as a keyboard, a pointing device, a display 118, etc.; one or more devices that enable a user to interact with computer system; and/or any devices (e.g., network card, modem, etc.) that enable computer system to communicate with one or more other computing devices. Such communication can occur via Input/Output (I/O) interfaces 110.

Still yet, the computer system can communicate with one or more networks 114 such as a local area network (LAN), a general wide area network (WAN), and/or a public network (e.g., the Internet) via network adapter 112. As depicted, network adapter 112 communicates with the other components of computer system via bus 104. It should be understood that although not shown, other hardware and/or software components could be used in conjunction with computer system. Examples include, but are not limited to: microcode, device drivers, redundant processing units, external disk drive arrays, RAID systems, tape drives, and data archival storage systems, etc.

Various embodiments may be implemented using hardware elements, software elements, or a combination of both. Examples of hardware elements may include processors, microprocessors, circuits, circuit elements (for example, transistors, resistors, capacitors, inductors, and so forth), integrated circuits, ASICs, programmable logic devices, digital signal processors, FPGAs, logic gates, registers, semiconductor devices, chips, microchips, chipsets, and so forth. Examples of software may include software components, programs, applications, computer programs, application programs, system programs, machine programs, operating system software, middleware, firmware, software modules, routines, subroutines, functions, methods, procedures, software interfaces, application program interfaces, instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power level, heat tolerances, processing cycle budget, input data rates, output data rates, memory resources, data bus speeds, and other design or performance constraints.

Some embodiments may be described using the expression “coupled” and “connected” along with their derivatives. These terms are not intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still cooperate or interact with each other.

The various embodiments disclosed herein can be implemented in various forms of hardware, software, firmware, and/or special purpose processors. For example, in one embodiment at least one non-transitory computer readable storage medium has instructions encoded thereon that, when executed by one or more processors, cause one or more of the network address configuration methodologies disclosed herein to be implemented. The instructions can be encoded using a suitable programming language, such as C, C++, object oriented C, Java, JavaScript, Visual Basic .NET, Beginner's All-Purpose Symbolic Instruction Code (BASIC), or alternatively, using custom or proprietary instruction sets. The instructions can be provided in the form of one or more computer software applications and/or applets that are tangibly embodied on a memory device, and that can be executed by a computer having any suitable architecture. In one embodiment, the system can be hosted on a given website and implemented, for example, using JavaScript or another suitable browser-based technology. For instance, in certain embodiments, the system may leverage processing resources provided by a remote computer system accessible via network. The computer software applications disclosed herein may include any number of different modules, sub-modules, or other components of distinct functionality, and can provide information to, or receive information from, still other components. These modules can be used, for example, to communicate with input and/or output devices such as a display screen, a touch sensitive surface, a printer, and/or any other suitable device. Other components and functionality not reflected in the illustrations will be apparent in light of this disclosure, and it will be appreciated that other embodiments are not limited to any particular hardware or software configuration. Thus in other embodiments system may comprise additional, fewer, or alternative subcomponents as compared to those included in the example embodiments.

The aforementioned non-transitory computer readable medium may be any suitable medium for storing digital information, such as a hard drive, a server, a flash memory, and/or random access memory (RAM), or a combination of memories. In alternative embodiments, the components and/or modules disclosed herein can be implemented with hardware, including gate level logic such as a field-programmable gate array (FPGA), or alternatively, a purpose-built semiconductor such as an application-specific integrated circuit (ASIC). Still other embodiments may be implemented with a microcontroller having a number of input/output ports for receiving and outputting data, and a number of embedded routines for carrying out the various functionalities disclosed herein. It will be apparent that any suitable combination of hardware, software, and firmware can be used, and that other embodiments are not limited to any particular system architecture.

Some embodiments may be implemented, for example, using a machine readable medium or article which may store an instruction or a set of instructions that, if executed by a machine, may cause the machine to perform a method and/or operations in accordance with the embodiments disclosed herein. Such a machine may include, for example, any suitable processing platform, computing platform, computing device, processing device, computing system, processing system, computer, process, or the like, and may be implemented using any suitable combination of hardware and/or software. The machine readable medium or article may include, for example, any suitable type of memory unit, memory device, memory article, memory medium, storage device, storage article, storage medium, and/or storage unit, such as memory, removable or non-removable media, erasable or non-erasable media, writeable or rewriteable media, digital or analog media, hard disk, floppy disk, compact disk read only memory (CD-ROM), compact disk recordable (CD-R) memory, compact disk rewriteable (CR-RW) memory, optical disk, magnetic media, magneto-optical media, removable memory cards or disks, various types of digital versatile disk (DVD), a tape, a cassette, or the like. The instructions may include any suitable type of code, such as source code, compiled code, interpreted code, executable code, static code, dynamic code, encrypted code, and the like, implemented using any suitable high level, low level, object oriented, visual, compiled, and/or interpreted programming language.

Unless specifically stated otherwise, it may be appreciated that terms such as “processing,” “computing,” “calculating,” “determining,” or the like refer to the action and/or process of a computer or computing system, or similar electronic computing device, that manipulates and/or transforms data represented as physical quantities (for example, electronic) within the registers and/or memory units of the computer system into other data similarly represented as physical quantities within the registers, memory units, or other such information storage transmission or displays of the computer system. The embodiments are not limited in this context.

The terms “circuit” or “circuitry,” as used in any embodiment herein, are functional and may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, firmware, etc. configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads, etc., in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system on-chip (SoC), desktop computers, laptop computers, tablet computers, servers, smart phones, etc. Other embodiments may be implemented as software executed by a programmable control device. In such cases, the terms “circuit” or “circuitry” are intended to include a combination of software and hardware such as a programmable control device or a processor capable of executing the software. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

Numerous specific details have been set forth herein to provide a thorough understanding of the embodiments. It will be understood by an ordinarily-skilled artisan, however, that the embodiments may be practiced without these specific details. In other instances, well known operations, components and circuits have not been described in detail so as not to obscure the embodiments. It can be appreciated that the specific structural and functional details disclosed herein may be representative and do not necessarily limit the scope of the embodiments. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications. It is intended that the scope of the present disclosure not be limited by this detailed description, but rather by the claims appended hereto. Future filed applications claiming priority to this application may claim the disclosed subject matter in a different manner, and may generally include any set of one or more elements as variously disclosed or otherwise demonstrated herein.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. An apparatus for cooling electronic components, comprising:
a chassis having a first side compartment having one or more electrical components and a second side compartment having one or more temperature sensitive electrical components;
a coolant channel running between the first side compartment and second side compartment; and
at least one thermoelectric cooler (TEC) positioned on the second side compartment, the TEC having a cold plate and a hot plate, the hot plate being coupled to the second side compartment and the cold plate being coupled to the one or more temperature sensitive electrical components.

2. The apparatus according to claim 1, wherein the second compartment further comprises one or more electrical components, wherein the electrical components are not temperature sensitive.

3. The apparatus according to claim 1, wherein the coolant channel is connected to a cooling loop of an internal combustion engine.

4. The apparatus according to claim 1, wherein the one or more electrical components include high temperature capacitors.

5. The apparatus according to claim 1, wherein the one or more temperature sensitive electrical components are contained on a circuit card assembly.

6. The apparatus according to claim 5, further including a heat spreader layer located between the at least one TEC and the circuit card assembly.

10. The apparatus according to claim 5, further including a copper surface layer located between the at least one TEC and the circuit card assembly.

11. The apparatus according to claim 5, further including a gap pad located between the at least one TEC and the circuit card assembly.

12. The apparatus according to claim 1, further comprising a thermal insulator positioned between second side compartment and the one or more temperature sensitive electrical components.

13. The apparatus according to claim 12, wherein the thermal insulator is configured to prevent heat transfer between the second side compartment and the one or more temperature sensitive electrical components.

14. The apparatus according to claim 1, wherein the at least one TEC is configured to bring a temperature of the one or more temperature sensitive electronic components below the temperature of the second side compartment.

15. A method for cooling electronic components using at least one thermoelectric cooler (TEC), the TEC having a cold plate and a hot plate, the method comprising:
providing an apparatus including a chassis having a first side compartment having one or more first electrical components and a second side compartment having one or more second electrical components, and a coolant channel positioned between the first side compartment and second side compartment, and wherein at least one of the first electrical components and the second electrical components are temperature sensitive electrical components;
identifying an amount of heat to be removed from the temperature sensitive electronic components;
determining TEC peak performance (PKP) according to the formula PKP=Delta T*N, where Delta T is the temperature difference between the hot plate and cold plate of the TEC, and N=HR/IP, where HR is the identified heat to be removed, and IP is the input power supplied to the TEC; and
positioning at least one TEC meeting the peak performance for the identified heat removal within at least one of the first side compartment and the second side compartment with the hot plate being coupled to at least one of the first side compartment and the second side compartment and the cold plate being coupled to the temperature sensitive electrical components.

16. The method according to claim 15, further including operating the at least one TEC to maintain the Delta T according to a predetermined relationship between input voltage and coefficient of performance of the at least one TEC.

17. The method according to claim 16, further including measuring the Delta T of the at least one TEC during operation and adjusting the input voltage to maintain the Delta T according to the predetermined relationship between input voltage and coefficient of performance of the at least one TEC.

18. A localized cooling system for electronics, comprising:
a dual chassis having a first side and a second side coupled together sharing a center section;
a cooling channel disposed in the central section;
at least one thermoelectric cooler (TEC) positioned on at least one of the first side and the second side, the TEC having a cold plate and a hot plate, wherein the hot plate is coupled to the first and/or second side; and the cold plate is connected to the one or more second electrical components.
one or more electrical components coupled to at least one of the first side and the second side; and
one or more temperature sensitive electrical components coupled to the cold plate.

19. The localized cooling system according to claim 1, wherein at least one of the temperature sensitive components is a circuit card assembly.

20. The localized cooling system according to claim 1, wherein the TEC is electrically coupled to a power source.
